(19) United States
(12) Patent Application Publication
(10) Pub. No.: US 2006/0258022 A1
(43) Pub. Date: Nov. 16, 2006

(54) Method for the calibration of radio frequency generator output power

(76) Inventor: Timothy L. Wright, Hillboro, OR (US)

Correspondence Address: DLA PIPER RUDNICK GRAY CARY US LLP, P. O. BOX 9271, RESTON, VA, 20195, US

(21) Appl. No.: 11/128,239

(22) Filed: May 13, 2005

(51) Int. Cl. H01L 21/00; H01L 21/66; C23F 1/00

(52) U.S. Cl. 438/10; 156/345.28; 438/17

(57) ABSTRACT

A method, system and computer-readable medium for calibrating the radio frequency power generator in a semiconductor processing system. The output of the radio frequency power generator is routed to a dummy load. An input control of the radio frequency power generator is adjusted to produce a desired output power conversion factors and calculated and used to control the radio frequency power generator.

### BACKGROUND OF THE INVENTION

1. Field of Invention

The invention relates to plasma process tools. More particularly, the present invention relates to the calibration of radio frequency generator power source output power levels.

2. Description of Background Information

Plasma processing systems are of considerable use in material processing, and in the manufacture and processing of semiconductors, integrated circuits, displays, and other electronic devices, both for etching and layer deposition on substrates, such as, for example, semiconductor wafers. Generally, the basic components of the plasma processing system include a chamber in which plasma is formed, a pumping region which is connected to a vacuum port for injecting and removing process gases, and a power source, generally a Radio Frequency (RF) generator, to form the plasma within the chamber. Additional components may include a chuck for supporting a wafer, and a power source to accelerate the plasma ions so the ions will strike the wafer surface with a desired energy to etch or form a deposit on the wafer. The power source used to create the plasma may also be used to accelerate the ions or different power sources may be used for each task.

To insure an accurate wafer is produced, typically, the power source is calibrated periodically to insure that a repeatable power is delivered to the processing chamber.

### SUMMARY OF THE INVENTION

The present invention provides a novel method and apparatus for the calibration of RF generators used as power sources in plasma processing.

### BRIEF DESCRIPTION OF THE DRAWINGS

In the accompanying drawings:

FIG. 1 is a simplified block diagram of a plasma processing system in accordance with an embodiment of the present invention.

FIG. 2 is a simplified block diagram of a plasma processing system in accordance with another embodiment of the present invention.

FIG. 3 is a simplified block diagram of a plasma processing system in accordance with another embodiment of the present invention.

FIG. 4 illustrates a method of calibrating a radio frequency power generator in accordance with an embodiment of the present invention.

FIG. 5 illustrates a method of computing calibration values for a radio frequency power generator in accordance with an embodiment of the present invention.

FIG. 6 shows an exemplary view of a power generator calibration screen in Single Mode in accordance with one embodiment of the present invention.

FIG. 7 shows an exemplary view of a power generator calibration screen in Mapping Mode in accordance with one embodiment of the present invention.

FIG. 8 shows an exemplary view of a power generator calibration results screen in Mapping Mode in accordance with one embodiment of the present invention.

FIG. 9 is a simplified block diagram of an apparatus for the automatic calibration of a power generator in accordance with one embodiment of the present invention.

FIG. 10 is a simplified block diagram of an apparatus for the automatic calibration of a power generator in accordance with another embodiment of the present invention.

### DETAILED DESCRIPTION

In the following description, for purposes of explanation, numerous specific details are set forth in order to provide a thorough understanding of the present invention. It will be evident, however, to one skilled in the art that the present invention may be practiced without these specific details. In some instances, well-known structures and devices are shown in block diagram form, rather than in detail, in order to avoid obscuring the present invention. These embodiments are described in sufficient detail to enable those skilled in the art to practice the invention, and it is to be understood that other embodiments may be utilized and that logical, mechanical, electrical, and other changes may be made without departing from the scope of the present invention.

Some portions of the detailed descriptions that follow are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of acts leading to a desired result. The acts are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present invention can be implemented by an apparatus for performing the operations herein. This apparatus may be specially constructed for the required purposes, or it may comprise a general-purpose computer, selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system.

The algorithms and displays presented herein are not inherently related to any particular computer or other apparatus. Various general purpose systems may be used with programs in accordance with the teachings herein, or it may prove convenient to construct more specialized apparatus to perform the required method. For example, any of the methods according to the present invention can be implemented in hard-wired circuitry, by programming a general-purpose processor or by any combination of hardware and software. One of skill in the art will immediately appreciate that the invention can be practiced with computer system configurations other than those described below, including hand-held devices, multiprocessor systems, microprocessor-based or programmable consumer electronics, DSP devices, network PCs, minicomputers, mainframe computers, and the like. The invention can also be practiced in distributed computing environments where tasks are performed by remote processing devices that are linked through a communications network. The required structure for a variety of these systems will appear from the description below.

The methods of the invention may be implemented using computer software. If written in a programming language conforming to a recognized standard, sequences of instructions designed to implement the methods can be compiled for execution on a variety of hardware platforms and for interface to a variety of operating systems. In addition, the present invention is not described with reference to any particular programming language. It will be appreciated that a variety of programming languages may be used to implement the teachings of the invention as described herein. Furthermore, it is common in the art to speak of software, in one form or another (e.g., program, procedure, application . . . ), as taking an action or causing a result. Such expressions are merely a shorthand way of saying that execution of the software by a computer causes the processor of the computer to perform an action or produce a result.

It is to be understood that various terms and techniques are used by those knowledgeable in the art to describe communications, protocols, applications, implementations, mechanisms, etc. One such technique is the description of an implementation of a technique in terms of an algorithm or mathematical expression. That is, while the technique may be, for example, implemented as executing code on a computer, the expression of that technique may be more aptly and succinctly conveyed and communicated as a formula, algorithm, or mathematical expression. Thus, one skilled in the art would recognize a block denoting A+B=C as an additive function whose implementation in hardware and/or software would take two inputs (A and B) and produce a summation output (C). Thus, the use of formula, algorithm, or mathematical expression as descriptions is to be understood as having a physical embodiment in at least hardware and/or software (such as a computer system in which the techniques of the present invention may be practiced as well as implemented as an embodiment).

A machine-readable medium is understood to include any mechanism for storing or transmitting information in a form readable by a machine (e.g., a computer). For example, a machine-readable medium includes read only memory (ROM); random access memory (RAM); magnetic disk storage media; optical storage media; flash memory devices; electrical, optical, acoustical or other form of propagated signals (e.g., carrier waves, infrared signals, digital signals, etc.); etc.

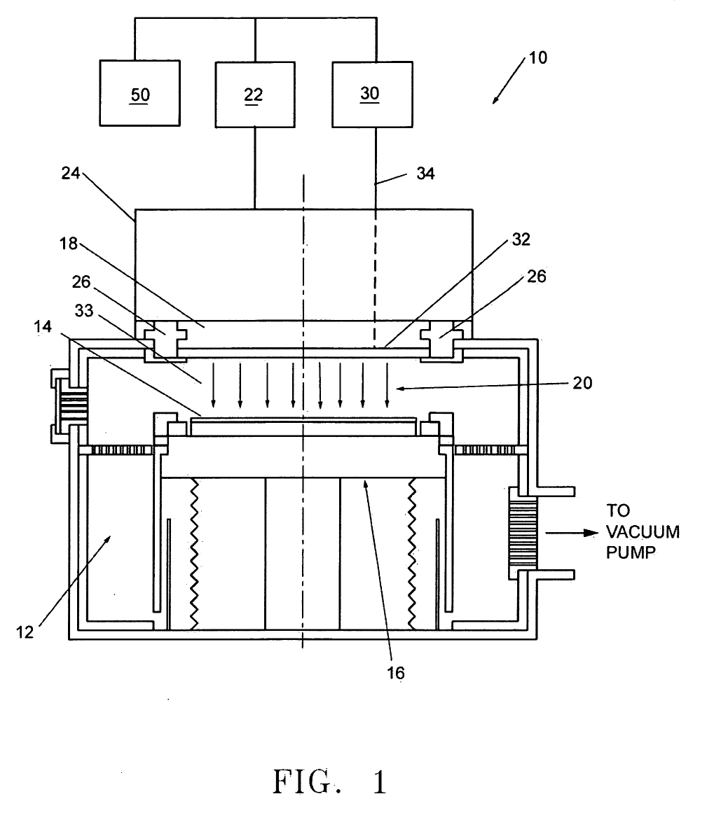

Referring now to FIG. 1, a plasma reactor 10 is shown to include a plasma chamber 12 that functions as a vacuum processing chamber adapted to perform plasma etching, from material deposition on, and/or chemical/mechanical alteration of a workpiece 14. The workpiece 14 can be, for example, a semiconductor substrate such as a silicon wafer. However, other types of substrates are also within the scope of the present invention. The plasma reactor 10 further includes chuck assembly 16 for holding the workpiece 14 and electrode assembly 18 for providing plasma energy to initiate the plasma. The chuck assembly 16 may be made movable to allow adjusting the distance between the chuck assembly 16 and the electrode assembly 18.

The electrode assembly 18 is arranged adjacent chuck assembly 16 to form plasma region 20. The electrode assembly 18 is capacitively coupled to the plasma when the workpiece 14 is being plasma processed, i.e. a capacitively coupled plasma (CCP) source assembly is used in plasma reactor 10. The plasma may have a plasma density (e.g., number of ions/volume, along with energy/ion) that is uniform, unless the density needs to be tailored to account for other sources of process non-uniformities or to achieve desired process non-uniformity. In order to protect the electrode assembly 18 and other components from heat damage due to the plasma, a cooling system (not shown) in fluid communication with electrode assembly 18 may be included for flowing a cooling fluid to and from the electrode assembly 18.

Electrode assembly 18 may be electrically connected to an RF power supply system 22 via electrode impedance match network 24. The impedance match network matches the impedance of power supply system 22 to the impedance of the electrode assembly 18 and the associated excited plasma. In this way, the power may be delivered by the RF power supply to the electrode assembly 18 and the associated excited plasma with reduced reflection. Insulator 26 is also provided to electrically decouple the electrode assembly 18 and associated impedance match network 24 from the wall of the process chamber 12 to allow onset of plasma in region 20 between electrode assembly 18 and chuck assembly 16.

In addition, the chuck assembly 16 used to support the workpiece 14, substrate or wafer can also be provided with an RF power supply (not shown) coupled thereto to bias the wafer.

The plasma reactor 10 further includes a gas supply system 30 in pneumatic communication with plasma chamber 12 via one or more gas conduits 34 for supplying gas in a regulated manner to form the plasma. Gas supply system 30 can supply gases such as chlorine, hydrogen-bromide, octafluorocyclobutane, or various other fluorocarbon compounds, and for chemical vapor deposition applications can supply silane, tungsten-tetrachloride, titanium-tetrachloride, or the like. In the CCP source assembly, the gases may be injected through gas inject/delivery assembly 32 opposite the chuck assembly 16 holding the substrate or wafer. Channels interconnecting a showerhead array of gas injection orifices can be formed within the gas inject assembly 32 to allow the gases to flow into plasma region 20 as illustrated by arrows 33, for example.

The gases injected in the chamber 12 are evacuated using a vacuum pump (not shown) which can be a turbo molecular pump. In this way, the gaseous environment all around the chuck assembly 16 in the process chamber 12 and particularly in the plasma region 20 is pumped by the vacuum pump.

Plasma reactor 10 may further include a main control system 50 to which RF power supply system 22, gas supply system 30, and other devices are electronically connected. In one embodiment, main control system 50 is a computer having a memory unit MU having both a random access memory (RAM) and a read-only memory (ROM), a central processing unit CPU, and a hard disk HD, all in electronic communication. Hard disk HD serves as a secondary computer-readable storage medium, and may be for example, a hard disk drive for storing information corresponding to instructions for controlling plasma reactor 10. The control system 50 may also include a disk drive DD, electronically connected to hard disk HD, memory unit MU and central processing unit CPU, wherein the disk drive is capable of reading and/or writing to a computer-readable medium CRM, such as a floppy disk or compact disc (CD) on which is stored information corresponding to instructions for control system 50 to control the operation of plasma reactor 10.

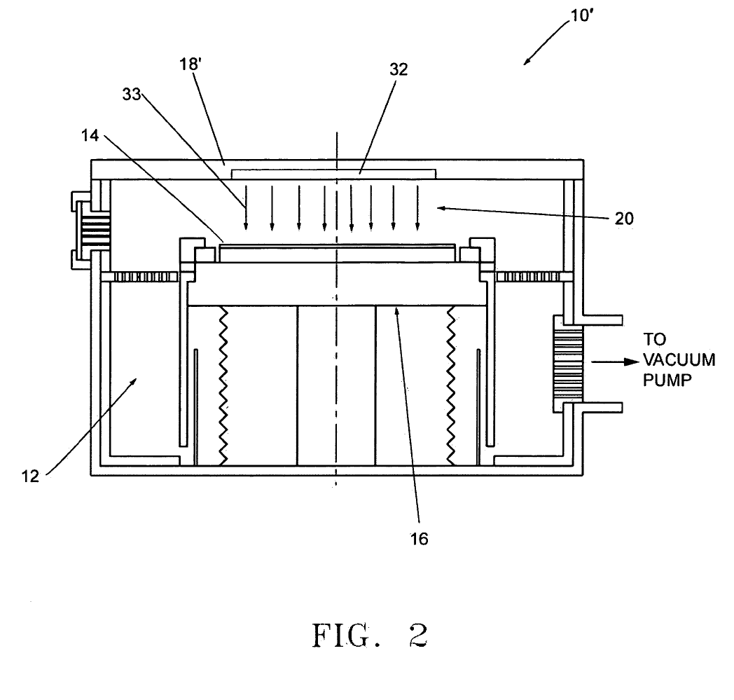

FIG. 2 is a cross-sectional view of a plasma reactor 10′ according to another embodiment of the present invention. This embodiment of the plasma reactor includes some of the same components of the first embodiment of plasma reactor except that in this embodiment the electrode assembly 18′ is connected to the ground and the chuck assembly 16 is biased with an RF voltage to allow onset of a plasma in plasma region 20.

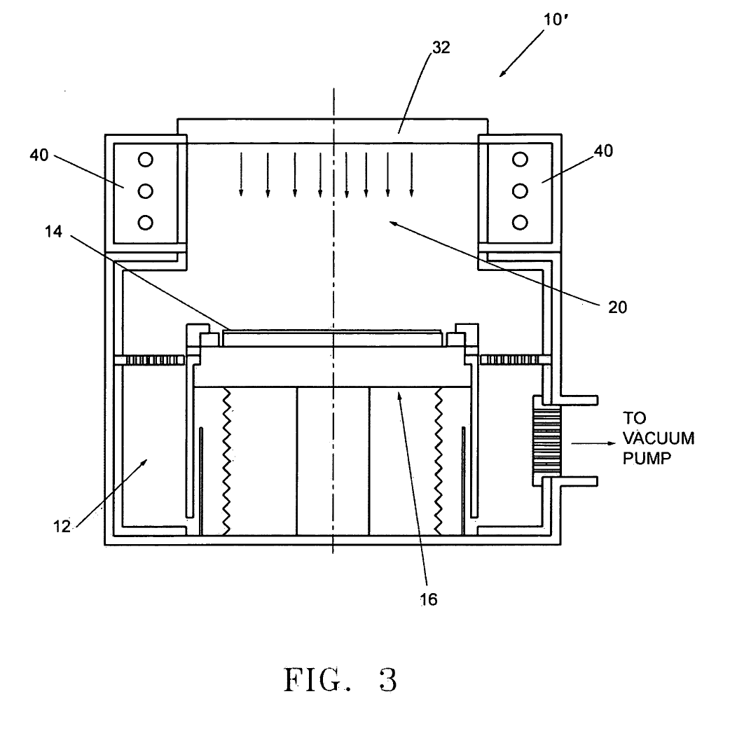

FIG. 3 is a cross-sectional view of a plasma reactor 10″ according to another embodiment of the present invention. This embodiment of the plasma reactor includes some of the same components of the first embodiment of plasma reactor except that in this embodiment an inductively coupled plasma (ICP) source 40 is used instead of a CCP source. Accordingly, the upper region of chamber 12 is adapted to include ICP source assembly 40, and a gas inject assembly 32. ICP source 40 can also include electrostatic shielding to form an electrostatically shielded radio frequency (ESRF) source. Regardless of the source of the RF energy, the plasma in the region 20 inside of the chamber 12 is excited by the RF energy that is generated by the respective RF power generators (not shown). In the ICP plasma source assembly, the gases may be injected through the gas inject assembly 32 opposite the chuck assembly 16 holding the substrate or wafer 14.

Although only capacitively coupled plasma (CCP) and inductively coupled plasma (ICP) sources have been described above, electron cyclotron resonance (ECR) reactors, Helicon wave plasma reactors, and the like can also be used. In fact, the power generator calibration method described below can be incorporated in any plasma apparatus that uses a radio frequency power source to generate process plasmas.

In the following discussion, a Tool Platform is defined as the physical structure upon which one or more plasma reactors and associated equipment, collectively referred to as process tools, may be mounted. The Tool Platform may provide mounting structures, power supply busses, gas line interfaces, digital data interfaces and other interfaces common to a plurality of process tools.

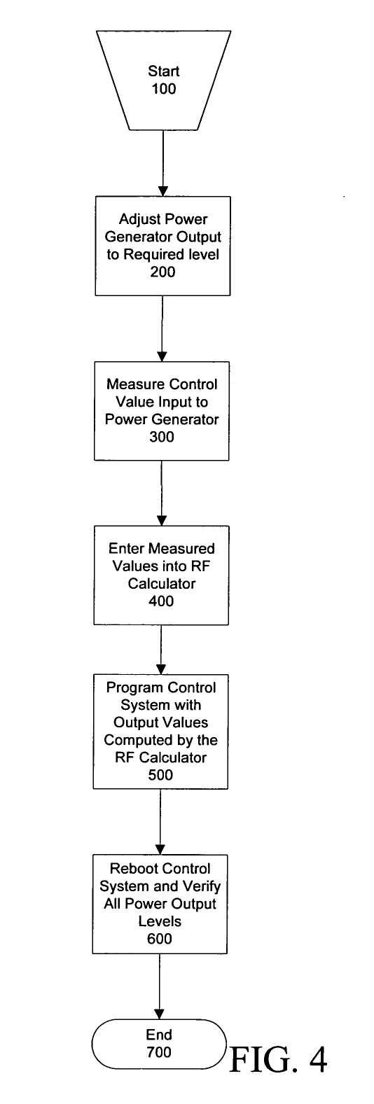

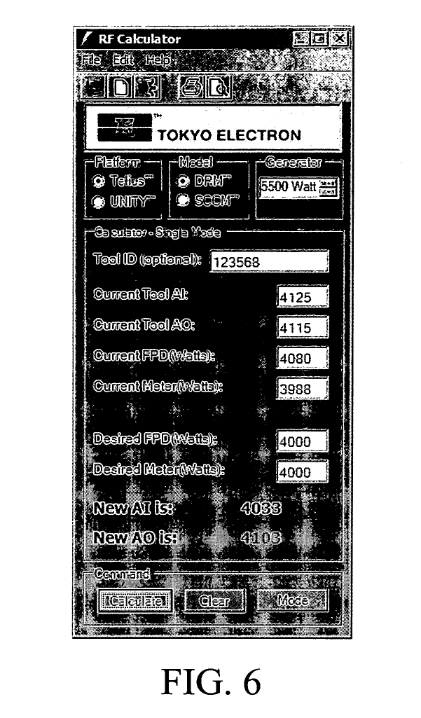

FIG. 4 illustrates a method of calibrating a radio frequency power generator as disclosed by this invention. In step 200, the control system output value to the power generator is adjusted until the desired power is delivered to a dummy load. The desired power levels are determined from historical metrology. Power is measured by a power meter in or associated with the dummy load. The desired power level is that power level at which optimum process results are achieved. At step 300 the operator measures this control system output voltage and, at step 400, enters the measured values into the RF calculator. FIG. 6 depicts an RF Calculator data entry screen for computing a single control system output value. Current tool values are entered and the RF Calculator displays New AI and AO values required to achieve desired power output levels. The values input into the RF Calculator include Current AI, the control value input to the control system; Current AO, the control value output from the control system to the power generator, Current FPD, the power value appearing on the control system's power display at the current values of AI and AO; Current Meter, the power measured by the power meter associated with the dummy load; Desired Meter, the power an operator desires to achieve as measured by the power meter associated with the dummy load; and Desired FPD, the corresponding power an operator desires to appear on the power display of the control system.

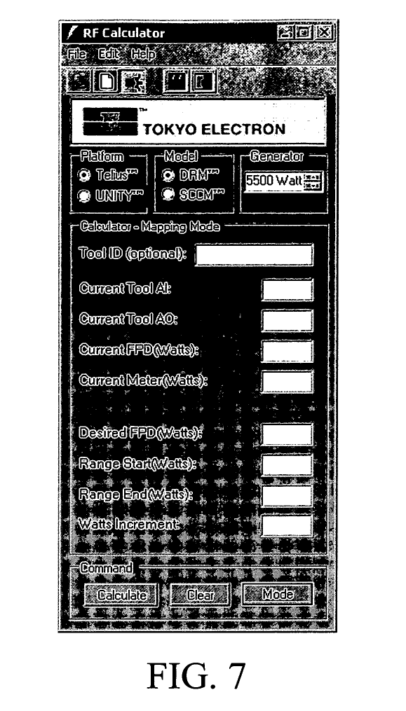

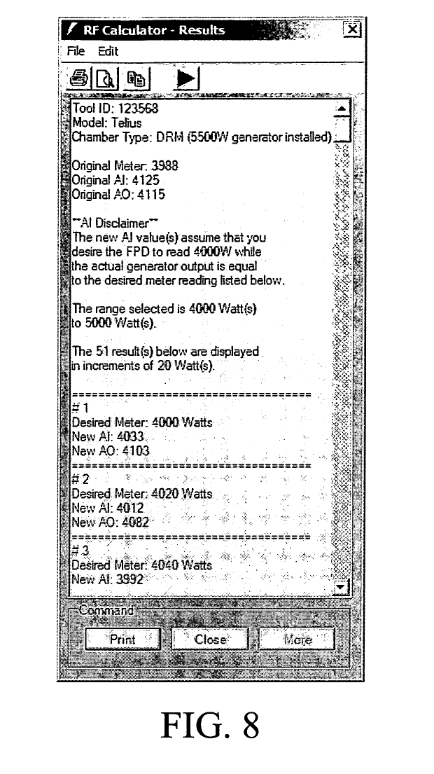

FIG. 7 depicts an RF Calculator data entry screen for computing a range of conversion factors computed for a range of desired power output levels from Range Start to Range End at an interval of Watts Increment. FIG. 8 depicts an RF Calculator data output screen displaying results computed from data entered as described for FIG. 7.

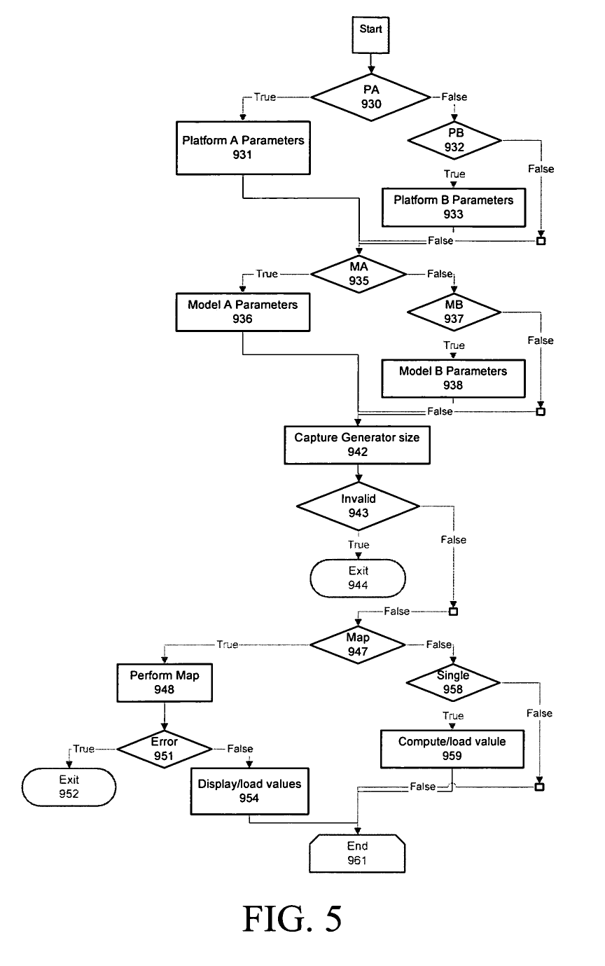

At step 500 the operator programs the control system with the values obtained from the RF calculator. At step 600 the control system is rebooted and power levels are verified by measuring the power delivered to the dummy load. The method of FIG. 5 does not require the repetition of the method of FIG. 4 and is therefore faster and less costly to implement.

FIG. 5 is a flow chart showing system operations for computing power generator set point values. In step 930 the RF calculator program performs a query to determine process tool platform type and loads computational values appropriate to the determined platform type, such as whether the platform responds to digital or analog command, control input voltage ranges and power output response curve parameters. Response curve parameters may be determined by common curve fitting techniques such as, but not limited to, linear least squares, weighted least squares, nonlinear least squares or other similar methods well known in the art. Once platform type is determined (steps 930-933), the process tool model type is determined (steps 935-938) and appropriate computational values are loaded corresponding to the model. The flow chart of FIG. 5 illustrates selection between two platforms and two models; however, expanding the code to select from among many platform types and models is obvious to those skilled in the art. At step 942 the RF power generator type is determined. Step 943 determines if the RF power generator type is appropriate for the process tool platform and model type. If an incorrect power generator type is determined an error is generated and the RF calculator program exits at step 944. At step 947 the RF calculator program determines if a range of power levels are to be determined or if a single calculation is to be performed. If a range of power levels are to be mapped, the appropriate values are computed at step 948 and error checked at step 951. The computation of the Output Value, AO, may be a simple linear relationship such as AO=kP_{L}, where P_{L} is the desired output power and k is a constant appropriate for the power generator selected. The computation of AO may also be more complex, involving, for example, an Nth order polynomial of the form AO=AP_{L}+BP_{L}²+CP_{L}³+ . . . +NP_{L}^{N}, where A, B, C and N are constants. AO can be determined based on the previously used AO and the characteristics of the tool. AI is related to AO in an established manner based on the control system. The computation may also be exponential, logarithmic, piecewise linear, or of any type appropriate to the platform and model chosen. If a computational error is detected, an out of range condition for example, the RF calculator program exits with an error flag at step 952. If no error is detected, the computed values are displayed at step 954. These values may also be automatically loaded to the process tool controller. If step 947 determines that a range of power values is not required, step 958 determines if a single calibration point is requested. The program exits at step 961 if no calibration has been requested. Step 959 performs the calculation for a requested single calibration point in the manner previously explained and loads the value to the display or process tool controller.

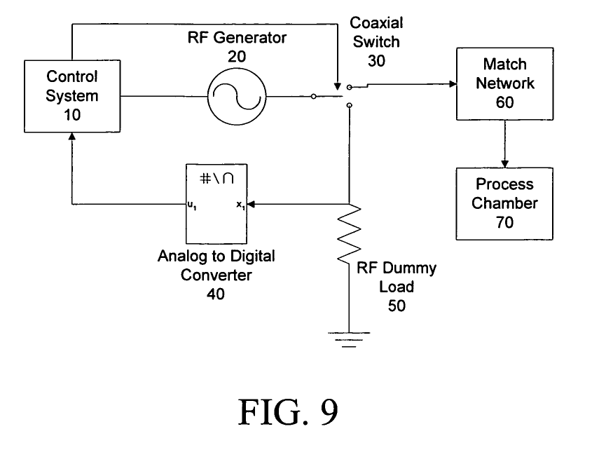

FIG. 9 illustrates an apparatus suitable for the automatic implementation of the method disclosed by this invention. Control system 10, RF generator 20, match network 60 and process chamber 70 are all standard components of previously described process tools. Coaxial switch 30, under the control of control system 10, switches the output of RF generator 20 between the match network 60 and the RF dummy load 50. With the RF generator output switched to the RF dummy load analog to digital converter 40 is used to provide the control system with a digital value corresponding to the power delivered to the dummy load. The method of FIG. 4 may then be implemented programmatically in control system 10. The start of the calibration sequence may be by operator command or at periodic intervals determined by operating hours or process cycles. After the calibration sequence is completed, the computed conversion factors can be verified by causing control system 10 to applying output values to the dummy load 50 and comparing measured power across the dummy load 50 to the desired power.

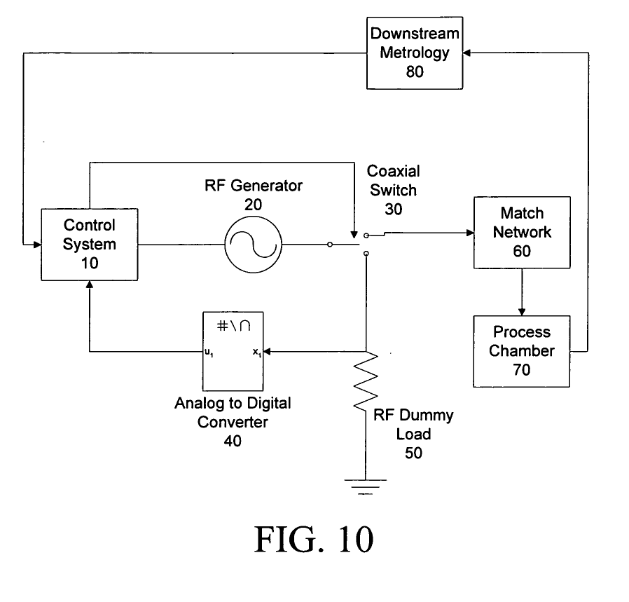

FIG. 10 illustrates the addition of downstream metrology 80 to the apparatus disclosed in FIG. 9 to provide a calibration start command to the control system 10. The downstream metrology 80 may be any of a variety of techniques including, but not limited to, scanning electron microscopy, ellipsometry, interferometry or other methods commonly used to evaluate a semiconductor process. A calibration start command may be issued to the control system when downstream metrology 80 detects process results consistent with incorrect RF power applied to the process chamber.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method of calibrating a radio frequency power generator in a semiconductor processing system including a controller system and a plasma processing system, the method comprising:
routing the output of the radio frequency power generator to a dummy load;
adjusting the radio frequency power generator input control to produce a desired output power;
computing radio frequency power generator conversion factors;
programming the controller system with the conversion factors; and
routing the output of the radio frequency power generator to the plasma processing system.

2. The method of claim 1, wherein:
computed conversion factors are verified by programming the controller system to apply power to the dummy load prior to reconnecting the radio frequency power generator to the plasma processing system.

3. The method of claim 1, wherein:
the controller system automatically performs the calibration upon operator command.

4. The method of claim 1, wherein:
the controller system automatically performs the calibration at scheduled intervals.

5. The method of claim 1, wherein:
the controller system automatically performs the calibration based upon input from downstream metrology.

6. A semiconductor processing system comprising:
a radio frequency power generator;
a dummy load selectively connectable to the radio frequency power generator; and
a controller system, coupled to a control input of the radio frequency power generator and the dummy load, the control system adjusting the control input to produce a desired output power across the dummy load, computing radio frequency power generation conversion factors, and using the power generation conversion factors to select control input values to obtain desired output power values from the radio frequency power generator.

7. A computer-readable medium tangibly embodying a program of instructions executable by a computer to perform a method of calibrating a radio frequency power generator, the method comprising:
routing the output of the radio frequency power generator to a dummy load;
adjusting the radio frequency power generator input control to produce a desired output power;
computing radio frequency power generator conversion factors;
programming the controller system with the conversion factors; and
routing the output of the radio frequency power generator to the plasma processing system.

8. Media as in claim 7 wherein the method further comprises:
verifying computed conversion factors by programming the controller system to apply power to the dummy load prior to reconnecting the radio frequency power generator to the plasma processing system.
